(19) United States
(12) Patent Application Publication
(10) Pub. No.: US 2016/0041227 A1
(43) Pub. Date: Feb. 11, 2016

(54) ON-LINE MONITORING SWITCH CONTACT LIFESPAN OF ON-LOAD TAP-CHANGER IN TRANSFORMERS

(71) Applicant: State Grid Shanxi Electric Power Corporation Yuncheng Power, Yuncheng City, Shanxi Province (CN)

(72) Inventors: Jinsheng Mao, (US); Jianjie Chen, (US); Jiang Qian, (US); Jiping Jin, (US); Shikui Zhang, (US); Chuangcheng Wang, (US)

(73) Assignee: State Grid Shanxi Electric Power Corporation Yuncheng Power, Yuncheng City, Shanxi Province (CN)

(21) Appl. No.: 14/400,972

(22) PCT Filed: Dec. 4, 2013
(86) PCT No.: PCT/CN2013/088480

§ 371 Date: Nov. 14, 2014

(30) Foreign Application Priority Data
Nov. 30, 2013 (CN) CN201310621540.7

(51) Int. Cl. G01R 31/327

(52) U.S. Cl. CPC G01R 31/327

(57) ABSTRACT

A device and a method are described for online monitoring the lifespan of switch contacts of a transformer on load tap changer (OLTC). The method includes connecting a current signal sensor of a voltage adjustment winding of the power transformer with a current signal processing circuit thereof; connecting the current signal sensor with an analog-digital converter of an industry control computer (IPC). When a switch signal is received, the switch current value and the number of switching operation of the OLTC are used for comparison with a lifespan relationship as a function of number of switch operations of a switch contact having similar specifications, wherein the relationship indicates a critical current value indicating the need for replacement. The device includes the IPC, the signal processing circuit, a monitor, and a keyboard.

### PRIORITY CLAIM

This application is a 371 filing of PCT/CN2013/088480 filed Dec. 4, 2013, which claims priority from Chinese application CN201310621540.7 filed Nov. 30, 2013, the disclosures of which are incorporated by reference in their entirety.

### TECHNICAL FIELD

The invention relates to devices and methods for on-line monitoring transformers having on-load tap-changers, in particular relates to devices and methods for on-line monitoring the lifespan of switch contacts of on-load tap-changer in transformers.

### TECHNICAL BACKGROUND

On-load tap-changer (OLTC) is an important component of power transformers, bearing voltage adjustment functions. The switch contact lifespan is crucial to the safe operation of transformer. Yet there has been a lack of good or scientifically reliable method for determining the lifespan of the switch contact. The Chinese Patent CN202230182U provides a device for online monitoring mechanical characteristics of an OLTC power transformer. The device can accurately determine and monitor mechanical aspects (e.g., interruption to rotating mechanical parts, loosening or mismatching of the switch contacts, phase misalignment, etc.) of the OLTC of the power transformer and can identify and diagnose any fault switch in the OLTC. Yet the device lacks the functions to determine the lifespan or conditions of switch contacts of the OLTC.

### SUMMARY OF THE INVENTION

This invention aims to overcome the problem identified above, i.e., to complement the lacking functions of the device in the Chinese Patent CN202230182U by providing devices and methods for online monitoring of the switch contacts of OLTC for determining the contacts' conditions or the related operation lifespan.

To realize the objectives, the invention adopted a technical solution as follows. A method for online monitoring lifespan of switch contact of on-load tap-changer (OLTC) of a power transformer comprises: connecting a current signal sensor of a voltage adjustment winding of the power transformer with a current signal processing circuit of the voltage adjustment winding; connecting the current signal sensor with an analog-digital converter of an industry control computer (IPC); receiving a switching signal to the IPC when the OLTC is in operation for voltage adjustment, wherein the switching signal is generated by a switch assistant contact and sent via a relay and an input-output (I/O) interface; reading, at the IPC, a current value passing through a voltage adjustment winding of the power transformer when the switch signal is received, the current value being the value of a switch current; accumulating a number of switching operation of the OLTC; calculating an instantaneous switching current value based on the read switch current value, the number of switch operations and an average value of previous switching currents; and comparing the instantaneous switching current value with a prediction current value based on the number of switch operations and a prediction curve describing a relationship between the number of switching operations and a current passing through a switch contact having similar specifications as the present switch contact, wherein the relationship indicates a critical current value for which the present switch contact needs replacement.

A device for online monitoring the lifespan of switch contacts of an OLTC in a power transformer, comprising: an industry control computer (IPC), a signal processing circuit, a display, and a keyboard, wherein the IPC, via an analogue to digital converter, is connected with a current signal acquisition unit for the voltage adjustment windings of the power transformer and a current signal processing circuit of the voltage adjustment windings of the power transformer.

The beneficial effect of the invention is to enable determination of the switch contact lifespan of OLTC in power transformers, thereby complementing functions in the device for online monitoring mechanical aspects of OLTC power transformers disclosed in the China Patent CN202230182U.

Detail descriptions of the invention is further provided below with figures and application examples.

### DESCRIPTION OF FIGURES

FIG. 1 is the schematic diagram for online monitoring for the mechanical characteristics of an OLTC in a power transformer according to Chinese patent CN202230182U.

FIG. 2 is a schematic diagram showing an embodiment of the current invention.

FIG. 3 is a plot showing the relationship between the switching cycle, switching current, and information relevant to switch contact's lifespan.

Drawing symbol description: 1. IPC(industry control computer); 2. vibration signal acquisition unit; 3. motor current signal acquisition unit; 4. shaft speed acquisition unit; 5. data receiving station; 6. current signal acquisition unit for transformer voltage regulating windings; n. number of switching operation; Iₚ. average switching current; Iₑ. rated current for OLTC switch; S. curve of switch contact lifespan.

### SPECIFIC WAY OF IMPLEMENTATION

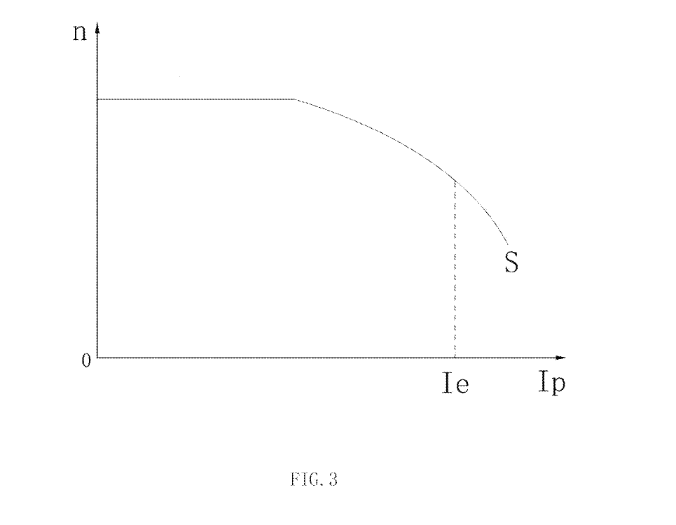

According to this invention, the method for online monitoring the lifespan of switch contact of OLTC in power transformers includes providing current signals from the transformer windings to a signal processing circuit. The current signals are then input to analog to digital (A/D) converter of the IPC 1. When the switching operation occurs at the OLTC, the assistant switch contact sends switching signals to the IPC 1 via I/O interface and a relay. When the CPU receives a switching signal, the current passing through the regulating winding is acquired as the switching current. The total number of switching operation is accumulated. The present switching current value is compared to an average switching current calculated from the accumulated number of switching operations, and obtains a present average switching current value. The lifespan of switch contacts is related to the switching current and the total number of switching operations. FIG. 3 shows a curve plot of the relationship between the number of switching cycles, switching current, and information relevant to switch contact's lifespan. In FIG. 3, n is the number of switching cycles; Iₚ is the average switching current; Iₑ. is the rated current for OLTC switch; and S is a general curve indicative of the lifespan of a switch contact. The general curve S is dependent from the manufacturer of the OLTC switch, the specific model, the rated current of the switch, the operation history, and the material and quality of the switch contact. A professional engineering and technical personnel with experience may create a specific curve similar to that in FIG. 3 for each particular type of switch contact as a reference. A switch contact may need be replaced when the average shift current value (Iₚ) and the number of switching (n) intersects with the lifespan curve (s).

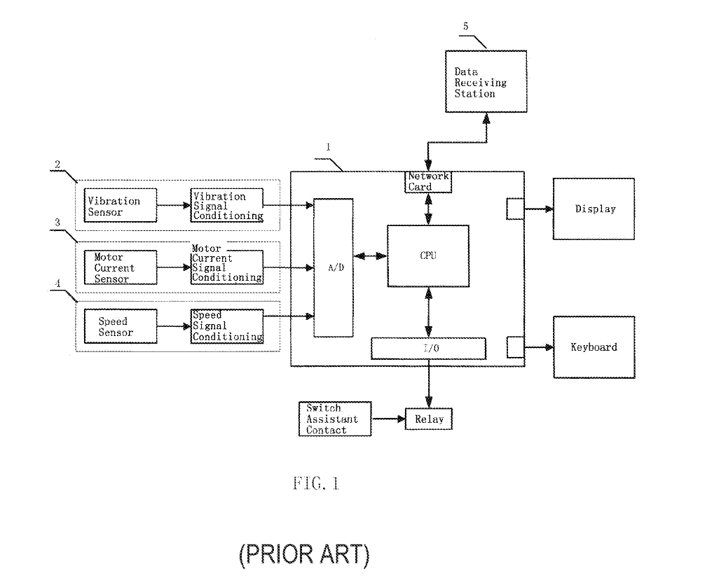

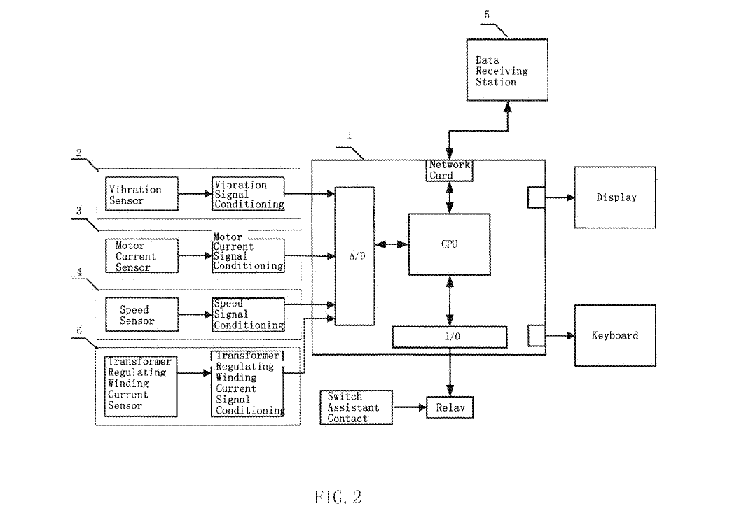

Referring now to FIG. 1, the schematic diagram for the online monitoring system for the mechanical characteristics of an OLTC in a power transformer according to Chinese patent CN202230182U is illustrated. The online monitoring system includes the IPC (1), various sensors and data acquisition units, signal processing circuits, monitors, and keyboards. The IPC (1) has a CPU for operably connecting or communicating the vibration signal acquisition unit (2), the motor current signal unit (3), and the shaft rotation rate acquisition unit (4) via the A/D converter. The IPC (1) communicates with the data receiving center (5) via a network interface (e.g., a network module). The IPC (1) further connects with the OLTC assistant switch contacts via an I/O input-output interface and relay. The IPC (1) is connected with a keyboard and a monitor. FIG. 2 is a schematic diagram showing an embodiment of the current invention of a system for online monitoring switch contacts' lifespan of OLTC in power transformers. The system shown in FIG. 2 improves upon the system shown in FIG. 1 by providing the functions of monitoring the lifespan of switch contacts. Detail implementation is as follows. Compared to the previous system of FIG. 1, the updated system includes a current signal acquisition unit (6) for the transformer voltage adjustment windings. The transformer voltage adjustment windings are connected to or coupled with the transformer windings current sensors, and further connected with the A/D converter of the IPC (1) via a current signal regulating circuit. When the OLTC switch is in operation, the switch assistant contact sends switching signals to the IPC (1) via the relay and the I/O interface. When the IPC (1) receives the switching signal, it reads the current passing through the voltage adjustment windings. The current value is also the value of the switching current. The IPC (1) retains the accumulated number of the switching operation, the instant value of the switching current, and the previously measured current value for calculating the current average switching current value. IPC (1) can then send the information, along with the accumulated number of switching operations, to the data receiving center via the network interface. The data receiving center then uses a predetermined curve S based on previously measured relationship between switching current and the number of switching operation to plat the average switching value and the number of switching operation. When the intersection point between the average switching current value and the number of switching operation intersects with the lifespan curve S, the switch contact reaches its lifespan.

1. A method for online monitoring lifespan of switch contact of on-load tap-changer (OLTC) of a power transformer, the method comprising:
connecting a current signal sensor of a voltage adjustment winding of the power transformer with a current signal processing circuit of the voltage adjustment winding;
connecting the current signal sensor with an analog-digital converter of an industry control computer (IPC);
receiving a switching signal at the IPC when the OLTC is in operation for voltage adjustment, wherein the switching signal is generated by a switch assistant contact and sent via a relay and an input-output (I/O) interface;
reading, at the IPC, a current value passing through a voltage adjustment winding of the power transformer when the switch signal is received, the current value being the value of a switch current;
accumulating a number of switching operation of the OLTC;
calculating an instantaneous switching current value based on the read switch current value, the number of switch operations and an average value of previous switching currents; and
comparing the instantaneous switching current value with a prediction current value based on the number of switch operations and a prediction curve describing a relationship between the number of switching operations and a current passing through a switch contact having similar specifications as the present switch contact, wherein the relationship indicates a critical current value for which the present switch contact needs replacement.

2. A device for online monitoring the lifespan of switch contacts of an OLTC in a power transformer, comprising: an industry control computer (IPC), a signal processing circuit, a display, and a keyboard, wherein the IPC, via an analogue to digital converter, is connected with a current signal acquisition unit for voltage adjustment windings of the power transformer and a current signal processing circuit of the voltage adjustment windings of the power transformer.

3. The device of claim 2, further comprising a switch contact of the OLTC, the switch contact alternating between an engaged state and a disengaged state; and an assistant switch contact for generating a switch signal of the switch contact.

4. The device of claim 3, wherein the IPC is connected to the assistant switch contact via an input-output interface and a relay.

5. The device of claim 4, wherein the IPC stores a reference curve of switch contact lifespan relating a current variation to a number of alterations measurable from the switch signal, the reference curve indicating a critical current value and a lifespan alteration number corresponding to the critical current value.

6. The device of claim 5, wherein a remaining portion of the lifespan of the switch contact is the difference between the number of alterations and the lifespan alteration number.

7. A method for online monitoring lifespan of a switch contact of on-load tap-changer (OLTC) of a power transformer, the method comprising:
measuring a current passing through a voltage adjustment winding of the power transformer;
counting a number of switching operations of the OLTC;
plotting the current as a function of the number of switching operations into a curve;
comparing the curve with a reference curve, wherein the reference curve indicating a critical current value for alerting replacement of the switch contact, the critical current corresponding to a lifespan number of switching operations; and
estimating the remaining available number of switching operations prior to reaching the lifespan number.

8. The method of claim 7, wherein measuring the current passing through a voltage adjustment winding further comprises connecting a current signal sensor to the voltage adjustment winding of the power transformer with a current signal processing circuit of the voltage adjustment winding.

9. The method of claim 8, wherein measuring the current passing through a voltage adjustment winding further comprises connecting the current signal sensor with an analog-digital converter of an industry control computer (IPC).

10. The method of claim 7, wherein counting the number of switching operations further comprises receiving a switching signal at the IPC when the OLTC is in operation for a voltage adjustment, wherein the switching signal is generated by a switch assistant contact and sent via a relay and an input-output interface.

11. The method of claim 7, wherein comparing the curve with a reference curve further comprises comparing the instantaneous value of the current with the critical current value corresponding to an allowable number of switch operations on the reference curve.

12. The method of claim 11, wherein estimating the remaining available number of switching operations equals to the difference between the allowable number of switching operations corresponding to the critical current value and the number of switching operations corresponding to the instantaneous value on the reference curve.

13. A system for online monitoring the lifespan of switch contacts of an OLTC in a power transformer, the system comprising:
a plurality of switch contacts of the OLTC, each of the plurality of switch contacts alternating between an engaged state and a disengaged state;
a plurality of voltage adjustment windings of the transformer each conducting a current passing therethrough;
a current signal acquisition unit operable to measure a current value passing through each of the plurality of voltage adjustment windings and at least one of the plurality of switch contacts;
a switch signal reader counting a number of alterations for each of the plurality of switch contacts between an engaged state and a disengaged state; and
a signal processor for processing the current values measured at the current signal acquisition unit and the number of alterations for each of the plurality of switch contacts for determining the condition of each of the plurality of the switch contacts.

14. The system of claim 13, further comprising an analog-digital converter for connecting the current signal acquisition unit to the signal processor.

15. The system of claim 13, wherein the signal processor is a central processing unit (CPU) of an industry control computer (IPC).

16. The system of claim 15, further comprising a plurality of assistant switch contacts for respectively generating the switch signals of the plurality of switch contacts.

17. The system of claim 16, wherein the IPC is connected with the plurality of assistant switch contacts via an input-output interface and a relay.

18. The system of claim 17, wherein the IPC stores a reference curve of switch contact lifespan relating a current variation to the number of alterations of the switch signal, the reference curve indicating a critical current value and a lifespan alteration number corresponding to the critical current value.

19. The system of claim 18, wherein the condition of each of the plurality of the switch contacts is the difference between the number of alterations of each switch contact and the lifespan alteration number.

20. The system of claim 19, further comprising a network interface operable to report the condition of each of the plurality of the switch contacts on a monitor screen for alerting prompt replacement of a switch contact near its end of lifespan.
